(19) United States
(12) Patent Application Publication
(10) Pub. No.: US 2022/0130735 A1
(43) Pub. Date: Apr. 28, 2022

(54) PACKAGE FOR POWER SEMICONDUCTOR DEVICE AND METHOD OF MANUFACTURING THE SAME

(71) Applicant: GM GLOBAL TECHNOLOGY OPERATIONS LLC, Detroit, MI (US)

(72) Inventors: Anthony M. Coppola, Rochester Hills, MI (US); Alireza Fatemi, Canton, MI (US); Erik B. Golm, Warren, MI (US); Ming Liu, Troy, MI (US)

(73) Assignee: GM GLOBAL TECHNOLOGY OPERATIONS LLC, Detroit, MI (US)

(21) Appl. No.: 17/078,690

(22) Filed: Oct. 23, 2020

(51) Int. Cl. H01L 23/46; H01L 21/48

(52) U.S. Cl. CPC H01L 23/46; H01L 21/4882

(57) ABSTRACT

A package for a power semiconductor device includes a housing, a power semiconductor module disposed within the housing, first and second fluidic channels extending through the housing on opposite sides of the power semiconductor module, and first and second arrays of heat transfer elements respectively disposed within the first and second fluidic channels. The first and second arrays of heat transfer elements are respectively physically bonded to first and second major surfaces of the power semiconductor module. A method of manufacturing a package for a power semiconductor device includes (i) respectively bonding first and second arrays of heat transfer elements to first and second major surfaces of a power semiconductor module, (ii) encapsulating the heat transfer elements within a sacrificial material, (iii) forming a housing around the sacrificial material and the heat transfer elements, and (iv) removing the sacrificial material from the housing to form first and second fluidic channels.

### INTRODUCTION

The present disclosure relates to power semiconductor modules, and more particularly to packaging systems for power semiconductor modules that include channels for transport of a heat transfer fluid.

Power semiconductor modules are used in power electronics systems, for example, as power converters and as power inverters of hybrid electric vehicles (HEVs) and in all electric vehicles (EVs). Such power semiconductor modules typically contain one or more power semiconductor devices (oftentimes referred to as semiconductor dies) carried on a substrate that may include electrically conductive regions that provide electrical connections to the semiconductor die. The substrate also may be thermally conductive and may provide a path for heat transfer away from the semiconductor die. In some power semiconductor modules, the semiconductor die may be sandwiched between two thermally conductive substrates (e.g., direct bonded copper (DBC) substrates) so that heat may be simultaneously removed from both sides of the semiconductor die. Heat may be transferred away from the substrate(s) and from the power semiconductor module itself, for example, via a thermal transfer material and, ultimately, via a heat transfer fluid. The performance of such power semiconductor modules can be improved by reducing the resistance to heat transfer between the semiconductor die and the heat transfer fluid, for example, by shortening the heat transfer path between the semiconductor die and the heat transfer fluid.

### SUMMARY

A package for a power semiconductor device may comprise a housing and a power semiconductor module disposed within the housing, in accordance with one or more embodiments of the present disclosure. The housing may have a longitudinal axis, a top, and a bottom. The power semiconductor module may have a first major surface and an opposite second major surface. A first fluidic channel and a second fluidic channel may be defined within the housing. The first fluidic channel may extend in a longitudinal direction parallel to the longitudinal axis of the housing between the top of the housing and the first major surface of the power semiconductor module. The second fluidic channel may extend in the longitudinal direction between the bottom of the housing and the second major surface of the power semiconductor module. A first array of heat transfer elements may be physically bonded to the first major surface of the power semiconductor module and disposed within the first fluidic channel. A second array of heat transfer elements may be physically bonded to the second major surface of the power semiconductor module and disposed within the second fluidic channel.

The housing may include an inlet disposed at a first end thereof and an outlet disposed at an opposite second end thereof. The inlet and the outlet of the housing may be in fluid communication with the first fluidic channel and with the second fluidic channel.

The power semiconductor module may comprise first and second heat transfer plates spaced apart from one another and disposed on opposite first and second sides of the power semiconductor module. In such case, the first major surface of the power semiconductor module may be at least partially defined by the first heat transfer plate and the second major surface of the power semiconductor module may be at least partially defined by the second heat transfer plate. The first array of heat transfer elements may be physically bonded to the first heat transfer plate of the power semiconductor module, and the second array of heat transfer elements may be physically bonded to the second heat transfer plate of the power semiconductor module.

Heat transfer fluid flowing in the longitudinal direction through the first fluidic channel may contact the first heat transfer plate of the power semiconductor module and the first array of heat transfer elements. Heat transfer fluid flowing in the longitudinal direction through the second fluidic channel may contact the second heat transfer plate of the power semiconductor module and the second array of heat transfer elements.

The first and second fluidic channels may be formed within the housing by removing a sacrificial material from the housing.

The package also may comprise a second power semiconductor module and a third power semiconductor module. The second power semiconductor module and the third power semiconductor module may be disposed within the housing. The power semiconductor modules may be positioned side-by-side in a linear or circular arrangement within the housing or the power semiconductor modules may be positioned in a stacked arrangement, one above another, in the housing.

A package for a power semiconductor device may comprise a housing and a power semiconductor module disposed within the housing, in accordance with one or more embodiments of the present disclosure. The housing may have a longitudinal axis, a top, and a bottom. The power semiconductor module may have a first major surface that faces toward the top of the housing and an opposite second major surface that faces toward the bottom of the housing. A first fluidic channel may extend in a longitudinal direction parallel to the longitudinal axis of the housing between the top of the housing and the first major surface of the power semiconductor module. A first array of heat transfer elements may be disposed within the first fluidic channel and may have proximal ends directly physically bonded to the first major surface of the power semiconductor module and opposite distal ends extending away from the power semiconductor module toward the top of the housing. A second fluidic channel may extend in the longitudinal direction between the bottom of the housing and the second major surface of the power semiconductor module. A second array of heat transfer elements may be disposed within the second fluidic channel and may have proximal ends directly physically bonded to the second major surface of the power semiconductor module and opposite distal ends extending away from the power semiconductor module toward the bottom of the housing. Heat transfer fluid flowing in the longitudinal direction through the first fluidic channel may contact the first major surface of the power semiconductor module and the first array of heat transfer elements. At the same time, heat transfer fluid flowing in the longitudinal direction through the second fluidic channel may contact the second major surface of the power semiconductor module and the second array of heat transfer elements.

The proximal ends of the first array of heat transfer elements each may be directly physically bonded to the first major surface of the power semiconductor module at discrete contact points, and the proximal ends of the second array of heat transfer elements each may be directly physically bonded to the second major surface of the power semiconductor module at discrete contact points.

The first array of heat transfer elements and the second array of heat transfer elements may be configured to respectively transfer heat away from the first and second major surfaces of the power semiconductor module via conduction. At the same time, heat transfer fluid flowing through the first and second fluidic channels may respectively transfer heat away from the first and second major surfaces of the power semiconductor module via convection.

The housing may be of unitary one-piece construction.

The housing may comprise an inlet disposed at a first end of the housing and an outlet in fluid communication with the inlet and disposed at an opposite second end of the housing. In such case, the inlet and the outlet of the housing may be in fluid communication with the first and second fluidic channels. In some embodiments, heat transfer fluid introduced into the inlet of the housing may be split between the first and second fluidic channels and reunited prior to being discharged from the outlet of the housing.

The top and the bottom of the housing may be discrete components and may be bonded to one another via an adhesive or sealant.

The power semiconductor module may comprise first and second heat transfer plates spaced apart from one another and disposed on opposite first and second sides of the power semiconductor module. In such case, the first major surface of the power semiconductor module may be at least partially defined by the first heat transfer plate and the second major surface of the power semiconductor module may be at least partially defined by the second heat transfer plate.

The power semiconductor module may comprise a body, a semiconductor die enclosed within the body, and a plurality of leads electrically connected to the semiconductor die and extending from the body in a lateral direction transverse to the longitudinal axis of the housing. One or more portions of the housing may be physically bonded to an outer peripheral region of the body of the power semiconductor module.

The housing may be made of a dielectric polymeric material, the first array of heat transfer elements may be made of a metal or ceramic material, and the second array of heat transfer elements may be made of a metal or ceramic material.

In some embodiments, the power semiconductor module may be a first power semiconductor module and the package may further include a second power semiconductor module positioned adjacent the first power semiconductor module within the housing. The second power semiconductor module may have a first major surface and an opposite second major surface. The first major surface of the second power semiconductor module may face toward the second major surface of the first power semiconductor module and toward the top of the housing. The opposite second major surface of the second power semiconductor module may face toward the bottom of the housing. The opposite distal ends of the second array of heat transfer elements may be directly physically bonded to the first major surface of the second power semiconductor module.

In a method of manufacturing a power semiconductor module package, a power semiconductor module, first array of heat transfer elements, and a second array of heat transfer elements may be provided. The power semiconductor module may include a body and a plurality of leads extending from opposite first and second ends of the body. The body of the power semiconductor module may have a first major surface and an opposite second major surface. A first intermediate assembly may be formed by bonding the first array of heat transfer elements to the first major surface of the power semiconductor module and bonding the second array of heat transfer elements to the second major surface of the power semiconductor module. A portion of the first intermediate assembly may be enclosed in a first mold such that a first void is defined between an interior surface of the first mold and one or more exterior surfaces of the first intermediate assembly. A second intermediate assembly may be formed by introducing a sacrificial material into the first mold such that the sacrificial material fills-in the first void. The second intermediate assembly may include the first intermediate assembly and the sacrificial material. A housing may be formed around a portion of the second intermediate assembly. Then, the sacrificial material may be removed from the second intermediate assembly to form a first fluidic channel and a second fluidic channel within the housing. The first fluidic channel may extend between the housing and the first major surface of the power semiconductor module and the second fluidic channel may extend between the housing and the second major surface of the power semiconductor module. The first fluidic channel and the second fluidic channel may be at least partially defined by the housing.

The first array of heat transfer elements may be bonded to the first major surface of the power semiconductor module and the second array of heat transfer elements may be bonded to the second major surface of the power semiconductor module by at least one of sintering, ultrasonic welding, or soldering.

The sacrificial material may be removed from the second intermediate assembly by at least one of melting, vaporizing, thermally decomposing, dissolving, or chemically etching the sacrificial material.

The housing may be formed around the portion of the second intermediate assembly by at least one of compression molding, vacuum forming, thermoforming, injection molding, blow molding, or profile extrusion.

The above summary is not intended to represent every possible embodiment or every aspect of the present disclosure. Rather, the foregoing summary is intended to exemplify some of the novel aspects and features disclosed herein. The above features and advantages, and other features and advantages of the present disclosure, will be readily apparent from the following detailed description of representative embodiments and modes for carrying out the present disclosure when taken in connection with the accompanying drawings and the appended claims.

### BRIEF DESCRIPTION OF THE DRAWINGS

Illustrative embodiments will hereinafter be described in conjunction with the appended drawings, wherein like designations denote like elements, and wherein:

FIG. 1 is a schematic perspective view of a package for a power semiconductor device, in accordance with one or more embodiments of the present disclosure, the package includes a housing, a power semiconductor module disposed within the housing, and a plurality of heat transfer elements physically bonded to opposite first and second major surfaces of the power semiconductor module;

FIG. 2 is a side cross-sectional view of the package of FIG. 1, taken in the Y-Z plane;

FIG. 3 is a side cross-sectional view of the package of FIG. 1, taken in the X-Z plane;

FIG. 4 is a side cross-sectional view of a first intermediate assembly positioned within a first mold during manufacture of the package of FIG. 1, the first intermediate assembly includes a power semiconductor module having first and second arrays of heat transfer elements respectively physically bonded to first and second major surfaces of the module, wherein a first void is defined between an interior surface of the first mold and one or more exterior surfaces of the first intermediate assembly;

FIG. 5 is a side cross-sectional view of the first intermediate assembly positioned within the first mold of FIG. 4, wherein a second intermediate assembly is formed by introducing a sacrificial material into the first void during manufacture of the package of FIG. 1; and

FIG. 6 is a side cross-sectional view of the second intermediate assembly of FIG. 5 positioned within a second mold, wherein a second void is defined between an interior surface of the second mold and one or more exterior surfaces of the second intermediate assembly, and wherein a housing is formed around the second intermediate assembly by introducing a dielectric polymeric material into the second void during manufacture of the package of FIG. 1.

The present disclosure is susceptible to modifications and alternative forms, with representative embodiments shown by way of example in the drawings and described in detail below. Aspects of this disclosure are not limited to the particular forms disclosed. Rather, the present disclosure is intended to cover modifications, equivalents, combinations, and alternatives falling within the scope of the disclosure as defined by the appended claims.

### DETAILED DESCRIPTION

The presently disclosed package may be configured for use in an integrated power conversion system, such as in a traction inverter and/or a DC/DC converter of a battery-powered electric vehicle (EV), a fuel cell vehicle, or a hybrid electric vehicle (HEV). The package includes a housing and a power semiconductor module disposed within the housing. The power semiconductor module has integral heat transfer elements that allow for the effective and efficient removal of heat from opposite first and second major surfaces of the power semiconductor module during operation thereof. The integral heat transfer elements are physically bonded to the first and second major surfaces of the power semiconductor module and are disposed within fluidic channels defined within the housing. Heat transfer fluid flowing through the fluidic channels in the housing contacts the first and second major surfaces of the power semiconductor module as well as the heat transfer elements, which minimizes the length of the heat transfer path between a semiconductor die contained within the power semiconductor module and the heat transfer fluid. As such, the integral heat transfer elements and the fluidic channels defined within the housing of the presently disclosed package allow heat to be transferred away from the power semiconductor module by a combination of heat transfer mechanisms, e.g., conductive, convective, and/or radiant heat transfer.

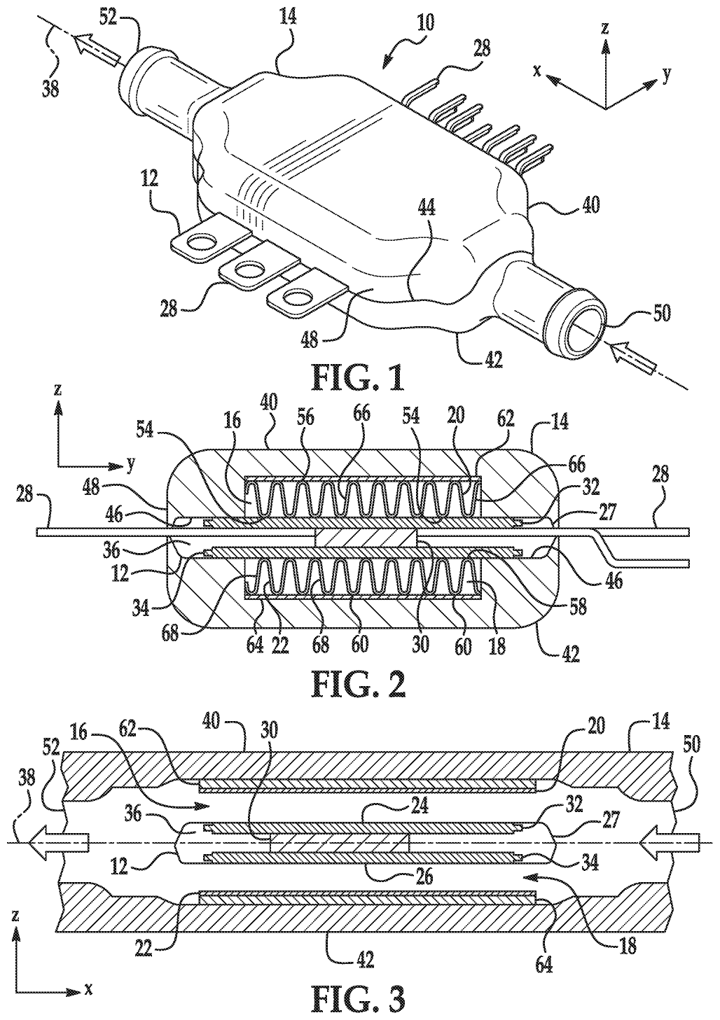

FIGS. 1-3 depict an exemplary embodiment of a package 10 for a power semiconductor device, in accordance with one or more embodiments of the present disclosure. The package 10 includes a power semiconductor module 12 disposed within a housing 14, first and second fluidic channels 16, 18 extending between the housing 14 and the power semiconductor module 12, and first and second arrays of heat transfer elements 20, 22 respectively disposed within the first and second fluidic channels 16, 18. In the embodiment depicted in FIGS. 1-3, a single power semiconductor module 12 is disposed within the housing 14. However, in other embodiments, the package 10 may include multiple power semiconductor modules (e.g., three power semiconductor modules) spaced apart from one another and disposed within the housing 14. In such case, the power semiconductor modules may be disposed side-by-side in a linear or circular arrangement, or the power semiconductor modules may be positioned in a stacked arrangement, one above the other, in the housing 14. In either case, each of the power semiconductor modules is directly physically bonded to a first array of heat transfer elements on a first side and a second array of heat transfer elements on an opposite second side thereof. In some embodiments, depending upon the arrangement of the power semiconductor modules within the housing 14, two adjacent power semiconductor modules may be spaced-apart from one another and an array of heat transfer elements may be sandwiched therebetween. In such case, the adjacent power semiconductor modules may be respectively physically bonded to opposite ends of the array of heat transfer elements. For example, in embodiments where two adjacent power semiconductor modules are positioned in a stacked arrangement within the housing 14, opposed surfaces of the adjacent power semiconductor modules may be respectively physically bonded to opposite ends of one array of heat transfer elements.

As best shown in FIGS. 2 and 3, the power semiconductor module 12 includes a body 27 and a plurality of leads 28 extending from opposite first and second ends of the body 27. The body 27 of the power semiconductor module 12 includes a first major surface 24, an opposite second major surface 26, and a heat source in the form of a power semiconductor die 30 enclosed therein. The semiconductor die 30 may be in the form of a bipolar transistor, an insulated-gate bipolar transistor (IGBT), a power metal-oxide-semiconductor field-effect transistor (MOSFET), a thyristor, or a diode. In the body 27 of the power semiconductor module 12, the semiconductor die 30 is electrically coupled to the leads 28, sandwiched between a pair of first and second heat transfer plates 32, 34, and encapsulated in a mold compound 36. The mold compound 36 may be made of a polymeric material, e.g., an epoxy-based or silicone-based polymeric material. Free ends of the leads 28 protrude outside of the mold compound 36 and may be coupled to an external power source (not shown).

The pair of first and second heat transfer plates 32, 34 are spaced apart from one another and disposed on opposite first and second sides of the body 27 of the power semiconductor module 12. The pair of first and second heat transfer plates 32, 34 are at least partially uncovered by the mold compound 36 such that the first major surface 24 of the body 27 of the power semiconductor module 12 is at least partially defined by the first heat transfer plate 32 and the second major surface 26 of the body 27 of the power semiconductor module 12 is at least partially defined by the second heat transfer plate 34. The first and second heat transfer plates 32, 34 may be made of a metal and/or ceramic material that exhibits high thermal conductivity (e.g., greater than about 20 W/m·K at ambient temperature) and a low coefficient of thermal expansion (e.g., less than 10 ppm/K at ambient temperature). As used herein, the term “metal” refers to elemental metals, as well as metal alloys that include a combination of an elemental metal and one or more metal or nonmetal alloying elements.

In some embodiments, the first and second heat transfer plates 32, 34 may exhibit a composite structure in the form of a metallized ceramic substrate, e.g., a ceramic substrate sandwiched between and directly bonded to layers or sheets of metal. The metallized ceramic substrate may be in the form of a direct bonded copper (DBC) ceramic substrate or a direct bonded aluminum (DBA) ceramic substrate. In either case, the ceramic substrate may be made of a ceramic material, e.g., aluminum-oxide (Al₂O₃), aluminum-nitride (AlN), and/or beryllium oxide (BeO). In DBC ceramic substrates, the ceramic substrate is sandwiched between and directly bonded to layers or sheets of copper (Cu) and/or copper oxide (CuO). In DBA ceramic substrates, the ceramic substrate is sandwiched between and directly bonded to layers or sheets of aluminum (Al).

The housing 14 electrically isolates the internal electrical components of the power semiconductor module 12 from the surrounding environment and prevents physical and electrical contact between heat transfer fluid flowing through the first and second fluidic channels 16, 18 of the power semiconductor module package 10 and the exposed free ends of the leads 28 of the power semiconductor module 12. The housing 14 has a central longitudinal axis 38, a top 40, a bottom 42, an inlet 50, and an outlet 52 in fluid communication with the inlet 50. The designations “top” and “bottom,” as used herein with respect to the top 40 and the bottom 42 of the housing 14 are for reference only as per the orientation shown and could alternatively be interchanged. The conventional system of axes X-Y-Z is used herein in which the X-axis extends in a longitudinal direction parallel to the longitudinal axis 38 of the housing 14, the Y-axis extends in a lateral direction transverse to the longitudinal axis 38 of the housing 14, and the Z-axis extends in a vertical direction transverse to the lateral and longitudinal directions.

The inlet 50 of the housing 14 is disposed at a first end of the housing 14 and the outlet 52 is disposed at an opposite second end of the housing 14. Both the inlet 50 and the outlet 52 of the housing 14 are in fluid communication with the first and second fluidic channels 16, 18. As such, heat transfer fluid introduced into the inlet 50 of the housing 14 may be split between the first and second fluidic channels 16, 18 and reunited prior to being discharged from the outlet 52 of the housing 14. The inlet 50 and/or the outlet 52 of the housing 14 may be defined by the top 40 and/or the bottom 42 of the housing 14.

In some embodiments, the housing 14 may be of unitary one-piece construction, with the top 40 and the bottom 42 of the housing 14 being formed of one integral piece of material. In such case, the housing 14 may be formed around the power semiconductor module 12 and around the first and second fluidic channels 16, 18 in a single manufacturing step. In other embodiments, the top 40 and the bottom 42 of the housing 14 may be formed as discrete components, positioned around the power semiconductor module 12, and then bonded to one another along an interface 44 therebetween, for example, using an adhesive or sealant (not shown). Portions 46 of the housing 14 that directly interface with an exterior surface of the power semiconductor module 12 may be physically bonded thereto, for example, during formation of the housing 14 itself or subsequent to formation of the housing 14, for example, using an adhesive or sealant (not shown). The adhesive or sealant used to bond the top 40 and the bottom 42 of the housing 14 to one another and/or to the exterior surface of the power semiconductor module 12 may be made of an elastomeric polymeric material, for example, that may be cured at room temperature. Such an adhesive or sealant may be a silicon-based polymeric material, e.g., a room-temperature-vulcanizing (RTV) silicone. The housing 14 may be made of a dielectric polymeric material, which may be a thermosetting or a thermoplastic polymeric material. The housing 14 may be made of the same polymeric material or a different polymeric material than that of the mold compound 36 of the power semiconductor module 12, e.g., an epoxy-based or silicone-based polymeric material.

When the power semiconductor module 12 is positioned within the housing 14, the first major surface 24 of the power semiconductor module 12 faces toward the top 40 of the housing 14 and the second major surface 26 of the power semiconductor module 12 faces toward the bottom 42 of the housing 14. At the same time, the leads 28 of the power semiconductor module 12 extend from opposite sides of the power semiconductor module 12 in a lateral direction transverse to the longitudinal axis 38 of the housing 14. The leads 28 protrude through a lateral sidewall 48 of the housing 14, beyond an outer periphery of the housing 14. The lateral sidewall 48 of the housing 14 may be defined by the top 40 and/or the bottom 42 of the housing 14 and extends in a vertical direction along the z-axis.

The first and second fluidic channels 16, 18 are in fluid communication with one another and with both the inlet 50 and the outlet 52 of the housing 14 and are configured to direct a flow of heat transfer fluid into direct contact with the first and second major surfaces 24, 26 of the power semiconductor module 12 and into direct contact with the first and second arrays of heat transfer elements 20, 22. As such, heat transfer fluid flowing through the first and second fluidic channels 16, 18 can effectively, efficiently, and directly transfer heat away from the first and second major surfaces 24, 26 of the power semiconductor module 12 and from the first and second arrays of heat transfer elements 20, 22 via convection. The first fluidic channel 16 extends through the housing 14 in a longitudinal direction parallel to the longitudinal axis 38 of the housing 14 between the top 40 of the housing 14 and the first major surface 24 of the power semiconductor module 12. The second fluidic channel 18 extends through the housing 14 in a longitudinal direction parallel to the longitudinal axis 38 of the housing 14 between the bottom 42 of the housing 14 and the second major surface 26 of the power semiconductor module 12. The first fluidic channel 16 is at least partially defined by the first major surface 24 of the power semiconductor module 12, an interior surface of the top 40 of the housing 14, and exterior surfaces 66 of the first array of heat transfer elements 20. At the same time, the second fluidic channel 18 is at least partially defined by the second major surface 26 of the power semiconductor module 12, an interior surface of the bottom 42 of the housing 14, and exterior surfaces 68 of the second array of heat transfer elements 22.

In embodiments where the power semiconductor module package 10 includes multiple power semiconductor modules 12 arranged side-by-side, heat transfer fluid introduced into the inlet 50 of the housing may flow through the first and second fluidic channels 16, 18 and in direct contact with the first and second major surfaces 24, 26 of the power semiconductor modules 12 sequentially, or one after the other. In embodiments where the power semiconductor module package 10 includes multiple power semiconductor modules 12 in a stacked arrangement, one above the other, heat transfer fluid introduced into the inlet 50 of the housing may flow through the first and second fluidic channels 16, 18 and in direct contact with the first and second major surfaces 24, 26 of the power semiconductor modules 12 at substantially the same time.

The first and second arrays of heat transfer elements 20, 22 are respectively disposed within the first and second fluidic channels 16, 18 and are configured to transfer heat away from the first and second major surfaces 24, 26 of the power semiconductor module 12 via conduction. To accomplish this, the first array of heat transfer elements 20 is physically bonded to the first major surface 24 of the power semiconductor module 12 and the second array of heat transfer elements 22 is physically bonded to the second major surface 26 of the power semiconductor module 12. The first array of heat transfer elements 20 may have proximal ends 54 directly physically bonded to the first major surface 24 of the power semiconductor module 12 and opposite distal ends 56 extending away from the power semiconductor module 12 toward the top 40 of the housing 14. The second array of heat transfer elements 22 may have proximal ends 58 directly physically bonded to the second major surface 26 of the power semiconductor module 12 and opposite distal ends 60 extending away from the power semiconductor module 12 toward the bottom 42 of the housing 14. The proximal ends 54 of the first array of heat transfer elements 20 each may be directly physically bonded to the first major surface 24 of the power semiconductor module 12 at a number of discrete spaced-apart contact points, and the proximal ends 58 of the second array of heat transfer elements 22 each may be directly physically bonded to the second major surface 26 of the power semiconductor module 12 at a number of discrete spaced-apart contact points.

In the embodiment depicted in FIG. 2, the first and second arrays of heat transfer elements 20, 22 are each defined by a separate unitary corrugated metal sheet that includes a plurality of ridges and grooves. The ridges and grooves of the corrugated metal sheet respectively define the proximal ends 54, 58 and the distal ends 56, 60 of the first and second arrays of heat transfer elements 20, 22. In other embodiments, the first and second arrays of heat transfer elements 20, 22 may exhibit different configurations. For example, the first and second arrays of heat transfer elements 20, 22 may be made-up of a plurality of discrete elongated structures (e.g., pillars, columns, wires, and/or fins), with each elongated structure having a proximal end directly physically bonded to the first or second major surface 24, 26 of the power semiconductor module 12 and an opposite distal end extending away from the power semiconductor module 12 toward the housing 14.

The first and second arrays of heat transfer elements 20, 22 may be made of a metal and/or ceramic material that exhibits high thermal conductivity (e.g., greater than about 20 W/m·K at ambient temperature) and a low coefficient of thermal expansion (e.g., less than 25 ppm/K and preferably less than 10 ppm/K at ambient temperature). For example, the heat transfer elements 20, 22 may be made of a copper-based or aluminum-based material. The first and second arrays of heat transfer elements 20, 22 may be made of the same material or of a different material than that of the first and second heat transfer plates 32, 34.

The first and second arrays of heat transfer elements 20, 22 may be respectively bonded to the first and second major surfaces 24, 26 of the power semiconductor module 12 using a low temperature joining process, i.e., a joining process accomplished at a temperature of less than 225° C., preferably less than 200° C., and more preferably less than 175° C. Examples of low temperature joining processes include sintering, ultrasonic welding, soldering, and/or solid-phase bonding. In embodiments where a solid-phase bonding process is used, the heat transfer elements 20, 22 may be respectively joined to the major surfaces 24, 26 of the power semiconductor module 12 without adding or otherwise producing a liquid-phase material therebetween. In embodiments where a sintering process is used, bonding of the heat transfer elements 20, 22 to the major surfaces 24, 26 of the power semiconductor module 12 may be accomplished using a metal-based sintering material. Examples of metal-based sintering materials include copper-based or silver-based films and pastes.

In some embodiments, as shown in FIGS. 1-3, the first and second arrays of heat transfer elements 20, 22 may be supported within the housing 14, for example, by respective first and second support plates 62, 64. In such case, the distal ends 56 of the first array of heat transfer elements 20 may be directly physically bonded to the first support plate 62 and the distal ends 60 of the second array of heat transfer elements 22 may be directly physically bonded to the second support plate 64. The first and second support plates 62, 64 may be made of a metal and/or ceramic material.

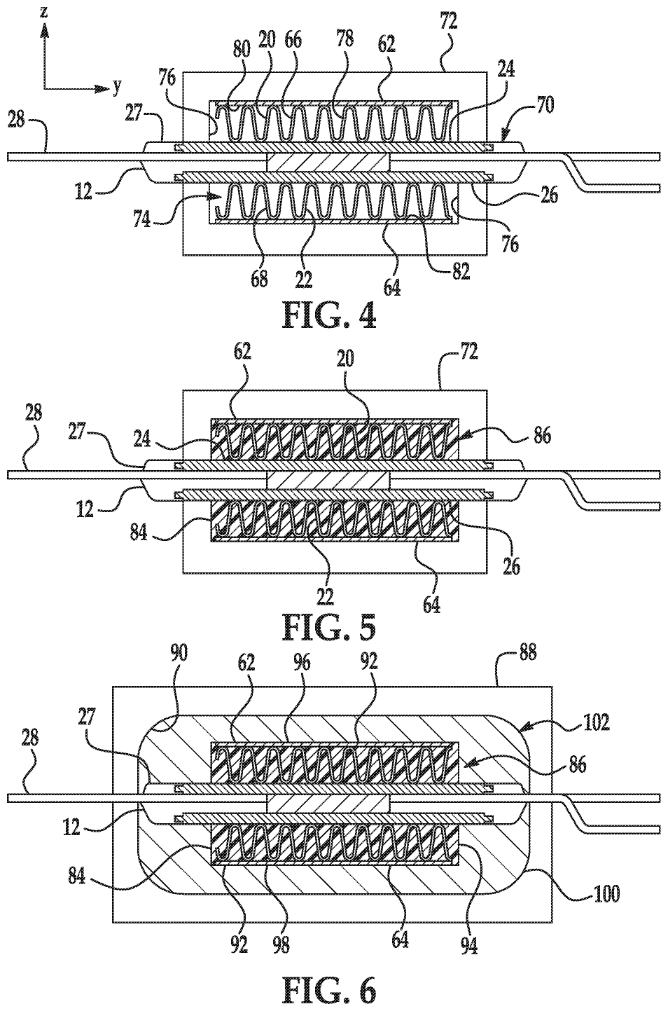

Referring now to FIGS. 4-6, the power semiconductor module package 10 may be manufactured by a method that includes one or more of the following steps.

In a first step, the proximal ends 54, 58 of the first and second arrays of heat transfer elements 20, 22 may be respectively bonded to the first and second major surfaces 24, 26 of the power semiconductor module 12 to form a first intermediate assembly 70, as shown in FIG. 4. The distal ends 56, 60 of the first and second arrays of heat transfer elements 20, 22 optionally may be respectively bonded to the first and second support plates 62, 64 to form the first intermediate assembly 70.

As shown in FIG. 4, in a second step, at least a portion of the first intermediate assembly 70 is enclosed within a first mold 72 such that a first void 74 is defined between an interior surface 76 of the first mold 72 and one or more exterior surfaces 78 of the first intermediate assembly 70. The one or more exterior surfaces 78 of the first intermediate assembly 70 may be defined by at least a portion of the first and second major surfaces 24, 26 of the power semiconductor module 12, by the exterior surfaces 66, 68 of the first and second arrays of heat transfer elements 20, 22, and optionally by respective inner surfaces 80, 82 of the first and second support plates 62, 64. The shape of the first mold 72 may be configured such that the first void 74 exhibits the desired shape of the first and second fluidic channels 16, 18.

Referring now to FIG. 5, in a third step, a sacrificial material 84 may be introduced into the first void 74 defined within the first mold 72 such that the sacrificial material 84 fills-in the first void 74 to form a second intermediate assembly 86 that includes the first intermediate assembly 70 and the sacrificial material 84. The sacrificial material 84 may be introduced into the first void 74, for example, by compression molding, vacuum forming, thermoforming, injection molding, blow molding, profile extrusion or a combination thereof. When the sacrificial material 84 is introduced into the first void 74, the sacrificial material 84 may completely cover the interior surface 76 of the first mold 72 and the one or more exterior surfaces 78 of the first intermediate assembly 70. The first and second arrays of heat transfer elements 20, 22 may be entirely encapsulated within the sacrificial material 84. In some embodiments, the sacrificial material 84 may be introduced into the first void 74 in the form of a liquid or relatively soft material and may be allowed to solidify or harden within the first void 74, for example, by cooling and/or by curing.

The sacrificial material 84 may be a material that can be removed from the second intermediate assembly 86 without harming the physical and/or structural integrity of the other components of the power semiconductor module package 10, e.g., the power semiconductor module 12, housing 14, first and second arrays of heat transfer elements 20, 22, and the first and second support plates 62, 64.

In some embodiments, the sacrificial material 84 may be a material that exhibits a solid phase at ambient temperature, but, upon heating to a temperature less than 175° C., transitions to a liquid phase or a gas phase. The sacrificial material 84 additionally or alternatively may be a material that exhibits a solid phase at ambient temperature, but thermally decomposes (e.g., pyrolyzes or oxidizes) upon heating to a temperature greater than ambient temperature but less than 175° C. In some embodiments, the sacrificial material 84 may be a material that is soluble in an aqueous medium (e.g., water) or a nonaqueous medium (e.g., acetone), or a material that can be dissolved by a chemical etchant (e.g., an acid such as hydrochloric acid, sulfuric acid, and/or nitric acid).

For example, the sacrificial material 84 may be a metal alloy solder having a melting point less than 175° C., e.g., a tin-based alloy solder. Examples of combustible materials that may be used for the sacrificial material 84 include black powder (i.e., a mixture of sulfur, charcoal, and potassium nitrate), pentaerythritol tetranitrate, a combustible metal, a combustible oxide, a thermite, nitrocellulose, pyrocellulose, a flash powder, and/or a smokeless powder. Such combustible materials may have flash points of less than 175° C. Examples of water-soluble materials that may be used for the sacrificial material 84 include inorganic salts and/or metal oxides, e.g., sodium chloride, potassium chloride, potassium carbonate, sodium carbonate, calcium chloride, magnesium chloride, sodium sulphate, magnesium sulfate, and/or calcium oxide. Examples of polymeric materials that may be formulated to thermally decompose at temperatures less than 175° C. and thus may be used for the sacrificial material 84 include polylactic acid (PLA), polyethylene terephthalate (PET), biaxially oriented polyethylene terephthalate (BOPET), cellulose, polypropylene, high density or low density polyethylene (HDPE, LDPE), acrylonitrile butadiene styrene (ABS), poly(alkylene carbonate) copolymers, and combinations thereof.

After the sacrificial material 84 has solidified or sufficiently hardened within the first void 74, the second intermediate assembly 86 may be removed from the first mold 72.

Referring now to FIG. 6, in a fourth step, at least a portion of the second intermediate assembly 86 may be enclosed within a second mold 88 such that a second void (not shown) is defined between an interior surface 90 of the second mold 88 and one or more exterior surfaces 92 of the second intermediate assembly 86. The one or more exterior surfaces 92 of the second intermediate assembly 86 may be defined by at least a portion of the body 27 of the power semiconductor module 12, by one or more exterior surfaces 94 of the sacrificial material 84, and optionally by respective outer surfaces 96, 98 of the first and second support plates 62, 64. For example, the one or more exterior surfaces 92 of the second intermediate assembly 86 may be defined by at least a portion of the first and second major surfaces 24, 26 of the body 27 of the power semiconductor module 12, by one or more exterior surfaces 94 of the sacrificial material 84, and optionally by respective outer surfaces 96, 98 of the first and second support plates 62, 64. The shape of the second mold 88 may be configured such that the second void defined between the interior surface 90 of the second mold 88 and the one or more exterior surfaces 92 of the second intermediate assembly 86 exhibits the desired shape of the housing 14.

As shown in FIG. 6, in a fifth step, a dielectric polymeric material 100 may be introduced into the second void defined within the second mold 88 such that the polymeric material 100 fills-in the second void to form a third intermediate assembly 102 that includes the second intermediate assembly 86 and the polymeric material 100. The polymeric material 100 may be introduced into the second mold 88, for example, by compression molding, vacuum forming, thermoforming, injection molding, blow molding, profile extrusion, or a combination thereof. When the polymeric material 100 is introduced into the second mold 88, the polymeric material 100 may completely cover the interior surface 90 of the second mold 88 and the one or more exterior surfaces 92 of the second intermediate assembly 86. In some embodiments, when the polymeric material 100 is introduced into the second mold 88, the polymeric material 100 may contact and physically bond with portions of the body 27 of the power semiconductor module 12.

The polymeric material 100 may be introduced into the second mold 88 in the form of a liquid or relatively soft malleable material and may be allowed to solidify or harden within the second mold 88, for example, by cooling and/or curing. The polymeric material 100 may be an epoxy, a polyurethane, a polyimide, a polypropylene, a nylon, a bismaleimide, a benzoxazine, a phenolic, a polyester, a polyvinylchloride, a melamine, a cyanate ester, a silicone, a vinyl ester, a thermoplastic olefin, a polycarbonate, a polyether sulfone, a polystyrene, a polytetrafluoroethylene, or a combination thereof.

Thereafter, in a sixth step, the sacrificial material 84 may be removed from the third intermediate assembly 102 to form the power semiconductor module package 10 (FIGS. 1-3).

The method used to remove the sacrificial material 84 from the third intermediate assembly 102 will depend upon the composition of the sacrificial material 84 and/or upon its chemical properties. In some embodiments, the sacrificial material 84 may be removed from the third intermediate assembly 102 by heating the assembly 102 to transform the sacrificial material 84 into a flowable liquid or a gas, and then allowing the sacrificial material 84 to flow out of the third intermediate assembly 102. In such case, the sacrificial material 84 may have a relatively low melting point, glass transition temperature, and/or sublimation temperature, i.e., a melting point, glass transition temperature, and/or sublimation temperature of less than 175° C. In other embodiments, the sacrificial material 84 may be removed from the third intermediate assembly 102 by heating the assembly 102 to pyrolyze, oxidize, and/or thermally decompose the sacrificial material 84. In such case, the sacrificial material 84 may have a relatively low flash point and/or thermal decomposition temperature, i.e., a flash point and/or thermal decomposition temperature of less than 175° C. In some embodiments, the sacrificial material 84 may be removed from the third intermediate assembly 102 by dissolving the sacrificial material 84 in an aqueous or nonaqueous medium, and then allowing the sacrificial material 84 to flow out of the third intermediate assembly 102 along with an aqueous or nonaqueous medium. In some embodiments, dissolution of the sacrificial material 84 may be accomplished using a chemical etchant.

The presently disclosed method allows for the formation of a unitary one-piece housing 14 around the body 27 of the power semiconductor module 12, as well as the formation and encapsulation of the first and second fluidic channels 16, 18 within the housing 14 so that heat transfer fluid can be introduced into the housing 14, passed through the first and second fluidic channels 16, 18 and into direct contact with the first and second major surfaces 24, 26 of the power semiconductor module 12, thereby facilitating the effective and efficient transfer of heat away from the power semiconductor module 12. These and other benefits will be readily appreciated by those of ordinary skill in the art in view of the forgoing disclosure.

While some of the best modes and other embodiments have been described in detail, various alternative designs and embodiments exist for practicing the present teachings defined in the appended claims. Those skilled in the art will recognize that modifications may be made to the disclosed embodiments without departing from the scope of the present disclosure. Moreover, the present concepts expressly include combinations and sub-combinations of the described elements and features. The detailed description and the drawings are supportive and descriptive of the present teachings, with the scope of the present teachings defined solely by the claims.

What is claimed is:

1. A package for a power semiconductor device, the package comprising:
a housing having a longitudinal axis, a top, and a bottom;
a power semiconductor module disposed within the housing and having a first major surface and an opposite second major surface;
a first fluidic channel extending in a longitudinal direction parallel to the longitudinal axis of the housing between the top of the housing and the first major surface of the power semiconductor module;
a first array of heat transfer elements physically bonded to the first major surface of the power semiconductor module and disposed within the first fluidic channel;
a second fluidic channel extending in the longitudinal direction between the bottom of the housing and the second major surface of the power semiconductor module; and
a second array of heat transfer elements physically bonded to the second major surface of the power semiconductor module and disposed within the second fluidic channel.

2. The package of claim 1 wherein the housing includes an inlet disposed at a first end thereof and an outlet disposed at an opposite second end thereof, and wherein the inlet and the outlet of the housing are in fluid communication with the first fluidic channel and with the second fluidic channel.

3. The package of claim 1 wherein the power semiconductor module comprises:
first and second heat transfer plates spaced apart from one another and disposed on opposite first and second sides of the power semiconductor module,
wherein the first major surface of the power semiconductor module is at least partially defined by the first heat transfer plate, and
wherein the second major surface of the power semiconductor module is at least partially defined by the second heat transfer plate.

4. The package of claim 3 wherein the first array of heat transfer elements is physically bonded to the first heat transfer plate of the power semiconductor module, and wherein the second array of heat transfer elements is physically bonded to the second heat transfer plate of the power semiconductor module.

5. The package of claim 4 wherein heat transfer fluid flowing in the longitudinal direction through the first fluidic channel contacts the first heat transfer plate of the power semiconductor module and the first array of heat transfer elements, and wherein heat transfer fluid flowing in the longitudinal direction through the second fluidic channel contacts the second heat transfer plate of the power semiconductor module and the second array of heat transfer elements.

6. The package of claim 1 wherein the first and second fluidic channels are formed within the housing by removing a sacrificial material from the housing.

7. The package of claim 1 further comprising a second power semiconductor module and a third power semiconductor module, wherein the second power semiconductor module and the third power semiconductor module are disposed within the housing, and wherein the power semiconductor modules are positioned side-by-side in a linear or circular arrangement within the housing or the power semiconductor modules are positioned in a stacked arrangement, one above another, in the housing.

8. A package for a power semiconductor device, the package comprising:
a housing having a longitudinal axis, a top, and a bottom;
a power semiconductor module disposed within the housing and having a first major surface that faces toward the top of the housing and an opposite second major surface that faces toward the bottom of the housing;
a first fluidic channel extending in a longitudinal direction parallel to the longitudinal axis of the housing between the top of the housing and the first major surface of the power semiconductor module;
a first array of heat transfer elements disposed within the first fluidic channel and having proximal ends directly physically bonded to the first major surface of the power semiconductor module and opposite distal ends extending away from the power semiconductor module toward the top of the housing;
a second fluidic channel extending in the longitudinal direction between the bottom of the housing and the second major surface of the power semiconductor module; and
a second array of heat transfer elements disposed within the second fluidic channel and having proximal ends directly physically bonded to the second major surface of the power semiconductor module and opposite distal ends extending away from the power semiconductor module toward the bottom of the housing,
wherein heat transfer fluid flowing in the longitudinal direction through the first fluidic channel contacts the first major surface of the power semiconductor module and the first array of heat transfer elements, and
wherein heat transfer fluid flowing in the longitudinal direction through the second fluidic channel contacts the second major surface of the power semiconductor module and the second array of heat transfer elements.

9. The package of claim 8 wherein the proximal ends of the first array of heat transfer elements are each physically bonded to the first major surface of the power semiconductor module at discrete contact points, and wherein the proximal ends of the second array of heat transfer elements are each physically bonded to the second major surface of the power semiconductor module at discrete contact points.

10. The package of claim 8 wherein the first array of heat transfer elements and the second array of heat transfer elements are configured to respectively transfer heat away from the first and second major surfaces of the power semiconductor module via conduction, and wherein heat transfer fluid flowing through the first and second fluidic channels can respectively transfer heat away from the first and second major surfaces of the power semiconductor module via convection.

11. The package of claim 8 wherein the housing is of unitary one-piece construction.

12. The package of claim 11 wherein the housing comprises an inlet disposed at a first end of the housing and an outlet in fluid communication with the inlet and disposed at an opposite second end of the housing, and wherein the inlet and the outlet of the housing are in fluid communication with the first and second fluidic channels.

13. The package of claim 12 wherein heat transfer fluid introduced into the inlet of the housing is split between the first and second fluidic channels and reunited prior to being discharged from the outlet of the housing.

14. The package of claim 8 wherein the top and the bottom of the housing are discrete components bonded to one another via an adhesive or sealant.

15. The package of claim 8 wherein the power semiconductor module comprises:
first and second heat transfer plates spaced apart from one another and disposed on opposite first and second sides of the power semiconductor module,
wherein the first major surface of the power semiconductor module is at least partially defined by the first heat transfer plate and the second major surface of the power semiconductor module is at least partially defined by the second heat transfer plate.

16. The package of claim 15 wherein the power semiconductor module further comprises:
a body;
a semiconductor die enclosed within the body; and
a plurality of leads electrically connected to the semiconductor die and extending from the body in a lateral direction transverse to the longitudinal axis of the housing.

17. The package of claim 16 wherein one or more portions of the housing are physically bonded to an outer peripheral region of the body of the power semiconductor module.

18. The package of claim 8 wherein the housing is made of a dielectric polymeric material, the first array of heat transfer elements are made of a metal or ceramic material, and wherein the second array of heat transfer elements are made of a metal or ceramic material.

19. The package of claim 8 wherein the power semiconductor module is a first power semiconductor module and the package further comprises a second power semiconductor module positioned adjacent the first power semiconductor module within the housing and having a first major surface and an opposite second major surface,
wherein the first major surface of the second power semiconductor module faces toward the second major surface of the first power semiconductor module and toward the top of the housing,
wherein the opposite second major surface of the second power semiconductor module faces toward the bottom of the housing, and
wherein the opposite distal ends of the second array of heat transfer elements are directly physically bonded to the first major surface of the second power semiconductor module.

20. A method of manufacturing a package for a power semiconductor device, the method comprising:
providing a power semiconductor module including a body and a plurality of leads extending from opposite first and second ends of the body, the body of the power semiconductor module having a first major surface and an opposite second major surface;
providing a first array of heat transfer elements;
providing a second array of heat transfer elements;
forming a first intermediate assembly by bonding the first array of heat transfer elements to the first major surface of the power semiconductor module and bonding the second array of heat transfer elements to the second major surface of the power semiconductor module;
enclosing a portion of the first intermediate assembly in a first mold such that a first void is defined between an interior surface of the first mold and one or more exterior surfaces of the first intermediate assembly;
forming a second intermediate assembly by introducing a sacrificial material into the first mold such that the sacrificial material fills-in the first void, wherein the second intermediate assembly includes the first intermediate assembly and the sacrificial material;
forming a housing around a portion of the second intermediate assembly; and
removing the sacrificial material from the second intermediate assembly to form a first fluidic channel and a second fluidic channel within the housing,
wherein the first fluidic channel extends between the housing and the first major surface of the power semiconductor module and the second fluidic channel extends between the housing and the second major surface of the power semiconductor module,
wherein the first fluidic channel and the second fluidic channel are at least partially defined by the housing,
wherein the first array of heat transfer elements is bonded to the first major surface of the power semiconductor module and the second array of heat transfer elements is bonded to the second major surface of the power semiconductor module by at least one of sintering, ultrasonic welding, or soldering, and
wherein the sacrificial material is removed from the second intermediate assembly by at least one of melting, vaporizing, thermally decomposing, dissolving, or chemically etching the sacrificial material.
